(19) United States
(12) Patent Application Publication
(10) Pub. No.: US 2008/0246149 A1
(43) Pub. Date: Oct. 9, 2008

(54) SEMICONDUCTOR DEVICE AND METHOD FOR FORMING DEVICE ISOLATION FILM OF SEMICONDUCTOR DEVICE

(75) Inventors: Byung Hun Kwak, Icheon-si (KR); Chi Hwan Jang, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/945,848

(22) Filed: Nov. 27, 2007

(30) Foreign Application Priority Data
Apr. 6, 2007 (KR) 10-2007-0034136

(51) Int. Cl. H01L 23/52; H01L 21/4763

(52) U.S. Cl. 257/751; 438/643; 257/E21.495; 257/E23.141

(57) ABSTRACT

A method for manufacturing a semiconductor device comprises growing a carbon nano tube (CNT) in a contact hole to form a contact plug, thereby preventing diffusion of a tungsten layer. The method does not require forming a titanium nitride (TiN) film deposited to improve an adhesive strength. The CNT has an excellent electric conductivity and a high mechanical strength to improve characteristics of the device.

### CROSS-REFERENCES TO RELATED APPLICATIONS

The priority benefit of Korean patent application number 10-2007-0034136, filed on Apr. 6, 2007 is hereby claimed and the disclosure thereof is incorporated herein by reference in its entirety.

### BACKGROUND OF THE INVENTION

The present invention relates to a semiconductor device and a method for forming a device isolation film of a semiconductor device.

A contact hole of a semiconductor device is configured to connect lower and upper conductive materials formed in a semiconductor substrate electrically.

That is, a contact hole is a path that penetrates an insulating film formed between lower and upper conductive materials. A conductive material formed in the contact hole connects the lower and upper conductive materials electrically.

Due to high integration of semiconductor devices, a diameter of a contact hole is decreased, and an alignment margin between the contact hole and the lower conductive material is reduced.

Also, a contact hole is required to have a smaller diameter than a minimum diameter defined by a photography process.

FIG. 1 is a cross-sectional diagram illustrating a conventional method for forming a contact plug of a semiconductor device.

An interlayer insulating film 160 is formed over a semiconductor substrate 150. The interlayer insulating film 160 is etched to form a contact hole that exposes the semiconductor substrate 150. After an aluminum (Al) layer, which is a metal conductive layer 170, is formed over the resulting structure including the contact hole, a contact plug is formed by a Chemical Mechanical Polishing (CMP) process.

The Al layer has a weak step coverage so that the Al layer is not filled in the contact hole but has a void as shown in ‘A’. The void increases a resistance of the contact plug to degrade an electric characteristic of the semiconductor device.

FIGS. 2a to 2c are cross-sectional diagrams illustrating a conventional method for forming a contact plug of a semiconductor device.

Referring to FIG. 2a, an interlayer insulating film 205 is formed over a semiconductor substrate 200.

The interlayer insulating film 205 is etched to form a contact hole 207 that exposes the semiconductor substrate 200.

A first metal barrier layer 210 and a second metal barrier layer 220 are sequentially formed over the contact hole 207.

The first metal barrier layer 210 and the second metal barrier layer 220 include a titanium (Ti) film and a titanium nitride (TiN) film, respectively. In a subsequent Ti and TiN process, a tungsten (W) layer formed with a contact plug is prevented from being diffused into the interlayer insulating film 205.

Referring to FIG. 2b, a tungsten (W) layer 230 is formed in the contact hole 207 to fill the contact hole 207.

A planarization process is performed until the interlayer insulating film 205 is exposed.

Referring to FIG. 2c, an Al layer, which is a metal conductive layer 240, is formed over the resulting structure including the tungsten layer 230 that fills the contact hole 207.

Although the tungsten layer prevents a void, as the size of the contact hole becomes smaller it causes a limit on the use of tungsten. As a result, a copper layer is used.

However, when the contact hole is filled with a copper layer, it is difficult to perform a dry etching process, and the copper causes environmental pollution.

In the above described method, the Al layer has a weak step coverage characteristic which results in generation of voids when the contact hole is filled, thereby degrading characteristics of the device.

Also, it is difficult to fill a fine contact hole with a tungsten layer, and to perform a dry etching on a copper layer.

### SUMMARY OF THE INVENTION

According to an embodiment of the present invention, a semiconductor device comprises a contact plug for connecting a lower conductive layer electrically to an upper conductive layer. The contact plug includes a carbon nano tube layer.

According to an embodiment of the present invention, a semiconductor device comprises a contact plug for connecting a lower conductive layer electrically to an upper conductive layer. The contact plug includes a metal barrier layer, a carbon nano tube pad layer formed over the metal barrier layer, and a carbon nano tube layer formed over the carbon nano tube pad layer.

A semiconductor device comprises a semiconductor substrate, an interlayer insulating film formed over the semiconductor substrate, a contact hole obtained by etching the interlayer insulating film, a metal barrier layer formed over the contact hole, a carbon nano tube growth pad layer formed in the bottom of the contact hole, and a carbon nano tube layer grown over the carbon nano tube growth pad layer to fill the contact hole.

The metal barrier layer preferably includes titanium. The carbon nano tube growth pad layer preferably includes nickel. The nickel layer preferably has a thickness in a range from about 10 Å to about 100 Å, more preferably in a range from about 45 Å to about 55 Å.

According to an embodiment of the present invention, a method for manufacturing a semiconductor device comprises: forming an interlayer insulating film over a semiconductor substrate; etching the interlayer insulating film to form a contact hole; forming a metal barrier layer over the contact hole; forming a carbon nano tube pad layer in the bottom of the contact hole; and growing a carbon nano tube over the carbon nano tube pad layer to fill the contact hole.

The metal barrier layer preferably includes titanium. The carbon nano tube pad layer preferably includes nickel. The method for forming the nickel layer preferably comprises: forming a mask pattern, which exposes the contact hole, over the interlayer insulating film; forming a nickel layer in the bottom of the contact hole with the mask pattern as a mask; and removing the mask pattern.

The nickel layer preferably has a thickness in a range from about 10 Å to about 100 Å, more preferably in a range from about 45 Å to about 55 Å. The carbon nano tube can be formed by one or more methods including but not limited to an electric discharge method, a laser deposition method, a plasma chemical vapor deposition method, a heat chemical vapor deposition method, a vapor synthesis method and an electrolysis method.

### BRIEF DESCRIPTION OF THE DRAWINGS

FIG. 1 is a cross-sectional diagram illustrating a conventional method for forming a contact plug of a semiconductor device.

FIGS. 2a to 2c are cross-sectional diagrams illustrating a conventional method for forming a contact plug of a semiconductor device.

FIGS. 3a to 3e are cross-sectional diagrams and SEM photographs illustrating a method for forming a contact plug of a semiconductor device according to an embodiment of the present invention.

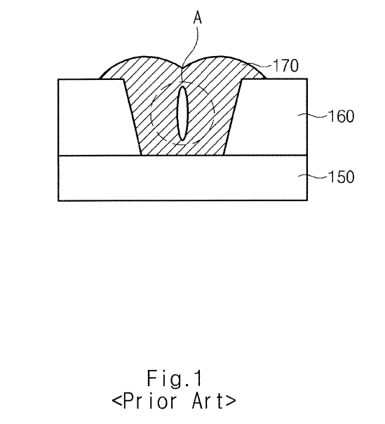

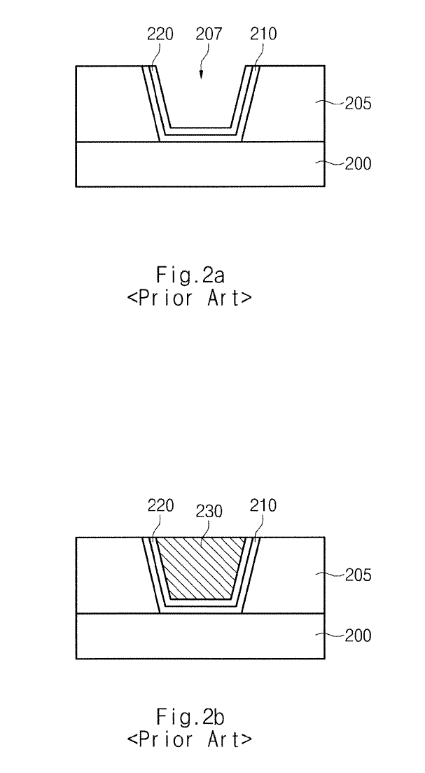

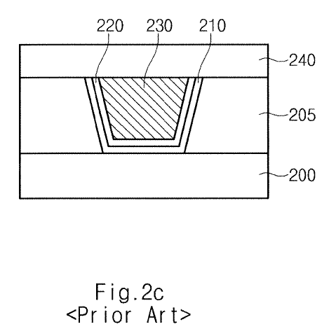

### DETAILED DESCRIPTION OF THE SPECIFIC EMBODIMENT

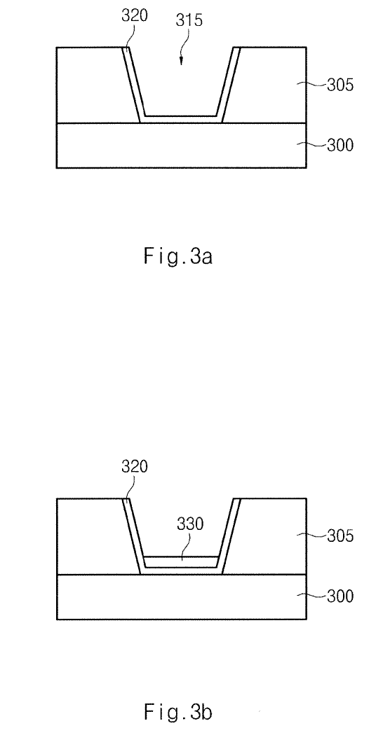

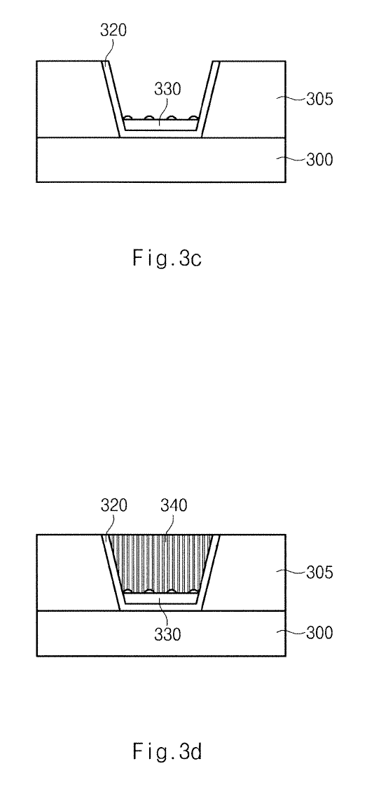

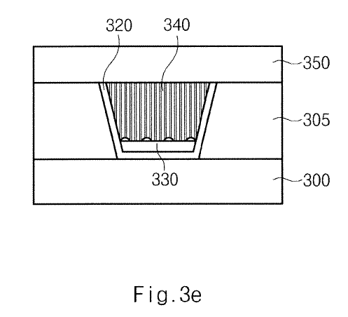

FIGS. 3a to 3e are cross-sectional diagrams illustrating a method for forming a contact plug of a semiconductor device according to an embodiment of the present invention.

Referring to FIG. 3a, an interlayer insulating film 305 is formed over a semiconductor substrate 300 including a lower conductive layer.

The interlayer insulating film 305 is etched to form a contact hole 315 for forming a contact.

A semiconductor substrate 300 is exposed by the contact hole 315.

A metal barrier layer 320 is formed over the contact hole 315. The metal barrier layer 320 improves a filling characteristic of a contact plug layer formed in a subsequent process, and prevents the contact plug layer from being diffused into the interlayer insulating film.

Referring to FIG. 3b, a mask layer (not shown) is formed over the resulting structure including the metal barrier layer 320. An etching process using a contact mask is performed to form a mask pattern (not shown) that exposes the contact hole 315.

A carbon nano tube growth pad layer 330 is formed over the semiconductor substrate, and the mask pattern is removed so that the carbon nano tube growth pad layer 330 remains only in the bottom of the contact hole 315 on the metal barrier layer 320.

The carbon nano tube growth pad layer 330 includes nickel to have a thickness in a range from about 10 Å to about 100 Å, preferably from about 44 Å to 55 Å.

The nickel layer serves as a seed layer in a growth process of a carbon nano tube (CNT) layer for filling the contact hole 315.

Referring to FIGS. 3c and 3d, a CNT layer 340 is grown over the resulting structure including the CNT pad layer 330 consisting of nickel, to fill the contact hole 315.

The CNT layer 340 can be grown by one or more of an electric discharge method, a laser deposition method, a plasma chemical vapor deposition method, a heat chemical vapor deposition method, a vapor synthesis method and an electrolysis method.

Referring to FIG. 3e, a planarization process is then performed to expose the interlayer insulating film 305, and then a metal conductive layer 350 is formed over the resulting structure.

The metal conductive layer 350 preferably includes aluminum (Al).

A CNT has an electric property regulated by a diameter and winding shape. The diameter can be grown to dozens of nm. The CNT an ultra fine single electron transistor or a silicon element to manufacture a memory device of Tera.

As described above, according to an embodiment of the present invention, a method for manufacturing a semiconductor device comprises growing a plurality of CNT to fill a contact hole, thereby preventing generation of voids of an aluminum contact plug. Also, the method facilitates a dry-etching process of copper and prevents an environmental pollution. The CNT has an excellent electric conductivity and a high mechanical strength to improve characteristics of the device.

The above embodiments of the present invention are illustrative and not limitative. Various alternatives and equivalents are possible. The invention is not limited by the lithography steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising a contact plug for connecting a lower conductive layer electrically to an upper conductive layer, the contact plug comprising a carbon nano tube layer.

2. A semiconductor device comprising a contact plug for connecting a lower conductive layer electrically to an upper conductive layer,
wherein the contact plug comprises:
a metal barrier layer;
a carbon nano tube pad layer formed over the metal barrier layer; and
a carbon nano tube layer formed over the carbon nano tube pad layer.

3. A semiconductor device comprising:
a semiconductor substrate;
an interlayer insulating film formed over the semiconductor substrate;
a contact hole in the interlayer insulating film;
a metal barrier layer formed over the contact hole;
a carbon nano tube growth pad layer formed in the bottom of the contact hole; and
a carbon nano tube layer grown over the carbon nano tube growth pad layer to fill the contact hole.

4. The semiconductor device according to claim 3, wherein the metal barrier layer comprises titanium.

5. The semiconductor device according to claim 3, wherein the carbon nano tube growth pad layer comprises a nickel layer.

6. The semiconductor device according to claim 5, wherein the nickel layer has a thickness in a range of about 10 Å to about 100 Å.

7. The semiconductor device according to claim 5, wherein the nickel layer has a thickness in a range of about 45 Å to about 55 Å.

8. A method for manufacturing a semiconductor device, the method comprising:
forming an interlayer insulating film over a semiconductor substrate;
etching the interlayer insulating film to form a contact hole;
forming a metal barrier layer over the contact hole;
forming a carbon nano tube pad layer in the bottom of the contact hole; and
growing a carbon nano tube over the carbon nano tube pad layer, to fill the contact hole.

9. The method according to claim 8, wherein the metal barrier layer comprises titanium.

10. The method according to claim 8, wherein the carbon nano tube pad layer comprises a nickel layer.

11. The method according to claim 10, wherein the step of forming the nickel layer further comprises:
forming a mask pattern, which exposes the contact hole, over the interlayer insulating film;
forming the nickel layer in the bottom of the contact hole with the mask pattern as a mask; and
removing the mask pattern.

12. The method according to claim 10, wherein the nickel layer has a thickness in a range of about 10 Å to about 100 Å.

13. The method according to claim 10, wherein the nickel layer has a thickness in a range of about 45 Å to about 55 Å.

14. The method according to claim 8, wherein the carbon nano tube is formed by one or more methods selected from the group consisting of an electric discharge method, a laser deposition method, a plasma chemical vapor deposition method, a heat chemical vapor deposition method, a vapor synthesis method and an electrolysis method.
